(19) United States
(12) Patent Application Publication
(10) Pub. No.: US 2015/0078102 A1
(43) Pub. Date: Mar. 19, 2015

(54) NONVOLATILE SEMICONDUCTOR MEMORY DEVICE AND DATA TRANSMISSION METHOD

(71) Applicant: KABUSHIKI KAISHA TOSHIBA, Tokyo (JP)

(72) Inventor: Tadashi YASUFUKU, Kanagawa (JP)

(73) Assignee: KABUSHIKI KAISHA TOSHIBA, Tokyo (JP)

(21) Appl. No.: 14/188,261

(22) Filed: Feb. 24, 2014

(30) Foreign Application Priority Data
Sep. 13, 2013 (JP) 2013-190690

(51) Int. Cl. G11C 7/10

(52) U.S. Cl. CPC G11C 7/1048
USPC 365/189.05

(57) ABSTRACT

A nonvolatile semiconductor memory device includes a first data latch, a second data latch, and a data bus between the first and second data latches. A first transistor is electrically connected between the first data latch and the data bus and a second transistor is electrically connected between the data bus and the second data latch. A control unit controls charging of the data bus based on an output of the first data latch.

### CROSS-REFERENCE TO RELATED APPLICATION

This application is based upon and claims the benefit of priority from Japanese Patent Application No. 2013-190690, filed Sep. 13, 2013, the entire contents of which are incorporated herein by reference.

### FIELD

Embodiments described herein relate generally to a nonvolatile semiconductor memory device and a data transmission method.

### BACKGROUND

Nonvolatile semiconductor memory devices such as a NAND type flash memory are known in the art.

### DESCRIPTION OF THE DRAWINGS

FIG. 1 is a circuit diagram illustrating an example of a configuration of a nonvolatile semiconductor memory device according to a first embodiment.

FIG. 2 is a block diagram illustrating an outline of input and output paths of data in the nonvolatile semiconductor memory device according to the first embodiment.

FIGS. 3A and 3B are circuit diagrams illustrating an example of configurations of data latches of the nonvolatile semiconductor memory device according to the first embodiment.

FIG. 4 is a waveform diagram illustrating an example of a data transmission operation of the nonvolatile semiconductor memory device according to the first embodiment.

FIG. 5 is a waveform diagram illustrating an example of a data transmission operation of the nonvolatile semiconductor memory device according to the first embodiment.

FIG. 6 is a diagram illustrating a measurement example of a power supply current of the nonvolatile semiconductor memory device according to the first embodiment.

FIG. 7 is a circuit diagram illustrating an example of a configuration of a nonvolatile semiconductor memory device according to a second embodiment.

FIG. 8 is a waveform diagram illustrating an example of a data transmission operation of the nonvolatile semiconductor memory device according to the second embodiment.

FIG. 9 is a waveform diagram illustrating an example of a data transmission operation of the nonvolatile semiconductor memory device according to the second embodiment.

FIG. 10 is a circuit diagram illustrating an example of a configuration of a nonvolatile semiconductor memory device according to a third embodiment.

FIG. 11 is a waveform diagram illustrating an example of a data transmission operation of the nonvolatile semiconductor memory device according to the third embodiment.

FIG. 12 is a waveform diagram illustrating an example of a data transmission operation of the nonvolatile semiconductor memory device according to the third embodiment.

FIG. 13 is a circuit diagram illustrating an example of a configuration of a nonvolatile semiconductor memory device according to a fourth embodiment.

FIG. 14 is a waveform diagram illustrating an example of a data transmission operation of the nonvolatile semiconductor memory device according to the fourth embodiment.

FIG. 15 is a circuit diagram illustrating an example of a configuration of a nonvolatile semiconductor memory device according to a fifth embodiment.

FIG. 16 is a waveform diagram illustrating an example of a calculation performed during a data transmission operation of the nonvolatile semiconductor memory device according to the fifth embodiment.

FIG. 17 is a waveform diagram illustrating an example of a calculation performed during the data transmission operation of the nonvolatile semiconductor memory device according to the fifth embodiment.

FIGS. 18A and 18B are diagrams illustrating truth tables of a logical calculation performed during the data transmission operation of the nonvolatile semiconductor memory device according to the fifth embodiment.

FIG. 19 is a waveform diagram illustrating an example of a calculation performed during the data transmission operation of the nonvolatile semiconductor memory device according to the fifth embodiment.

FIG. 20 is a diagram illustrating a truth table of a logical calculation performed during the data transmission operation of the nonvolatile semiconductor memory device according to the fifth embodiment.

### DETAILED DESCRIPTION

The present exemplary embodiments provide a nonvolatile semiconductor memory device and a data transmission method capable of reducing power consumption and performing data calculation speedily.

In general, according to one embodiment, a nonvolatile semiconductor memory device includes a first data latch, a second data latch, a data bus, a first transistor electrically connected between the first data latch and the data bus, a second transistor electrically connected between the data bus and the second data latch, and a control unit configured to control charging of the data bus based on an output of the first data latch.

Hereinafter, embodiments will be described with reference to the drawings. In addition, in the drawings, identical or corresponding parts are given the same reference number, and description thereof will not be repeated.

In addition, in the following description, a logical value of each signal is expressed by positive logic, and a logical value ‘1’ is set if a level of each signal is an H (high) level, and a logical value ‘0’ is set if a level of each signal is an L (low) level.

### First Embodiment

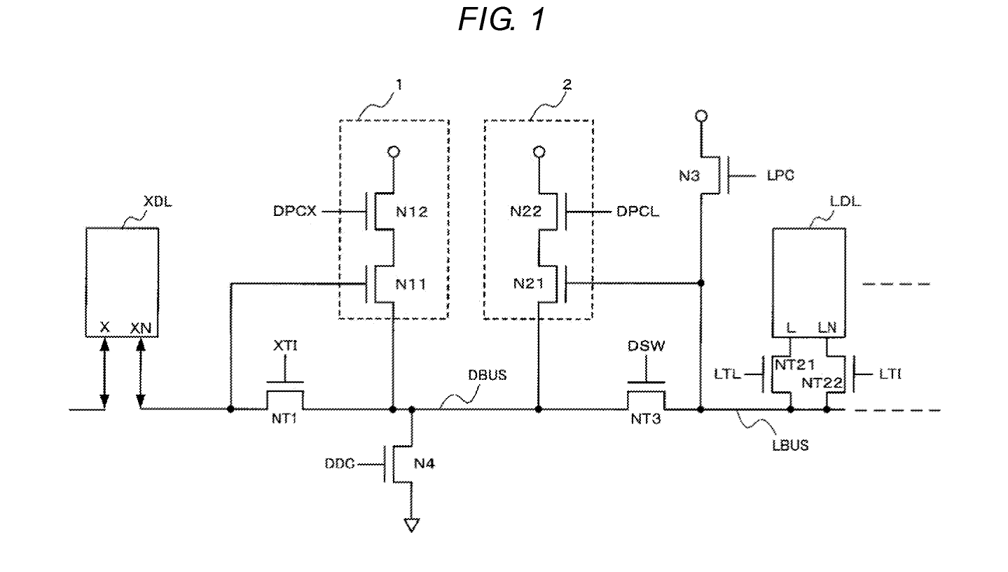

FIG. 1 is a circuit diagram illustrating an example of a configuration of a nonvolatile semiconductor memory device according to the first embodiment.

The nonvolatile semiconductor memory device according to the present embodiment includes a data latch XDL (a first data latch); a data latch LDL (a second data latch); a data bus DBUS (a first data bus); a data bus LBUS (a second data bus); a transmission gate NT1 (a first transmission gate) electrically connected to the data latch XDL and the data bus DBUS; transmission gates NT21 and NT22 (a second transmission gate) electrically connected to the data latch LDL and the data bus LBUS; a transmission gate NT3 (a third transmission gate) electrically connected to the data bus DBUS and the data bus LBUS; a precharge control unit 1 (a first precharge control unit) connected between a power supply terminal and the data bus DBUS; and a precharge control unit 2 (a second precharge control unit) connected between the power supply terminal and the data bus DBUS.

In addition, the nonvolatile semiconductor memory device according to the present embodiment includes an NMOS transistor N3 which precharges the data bus LBUS, and an NMOS transistor N4 which releases electric charge on the data bus DBUS.

The NMOS transistor N3 precharges the data bus LBUS when a control signal LPC which is input to a gate terminal thereof is ‘1’. The NMOS transistor N4 releases electric charge on the data bus DBUS when a control signal DDC which is input to a gate terminal thereof is ‘1’.

The transmission gate NT1 is formed by an NMOS transistor, and is connected between an inverting data terminal XN of the data latch XDL and the data bus DBUS. The transmission gate NT1 performs data transmission between the inverting data terminal XN of the data latch XDL and the data bus DBUS when a control signal XTI which is input to a gate terminal thereof is ‘1’.

The transmission gates NT21 and NT22 are formed by an NMOS transistor, and are respectively connected between a non-inverting data terminal L and an inverting data terminal LN of the data latch LDL and the data bus LBUS. The transmission gates NT21 and NT22 respectively perform data transmission between the non-inverting data terminal L and the inverting data terminal LN of the data latch LDL and the data bus LBUS when control signals LTL and LTI which are respectively input to gate terminals thereof are ‘1’.

The circuit illustrated in FIG. 1 is used as, for example, a bit line control circuit of a NAND flash memory.

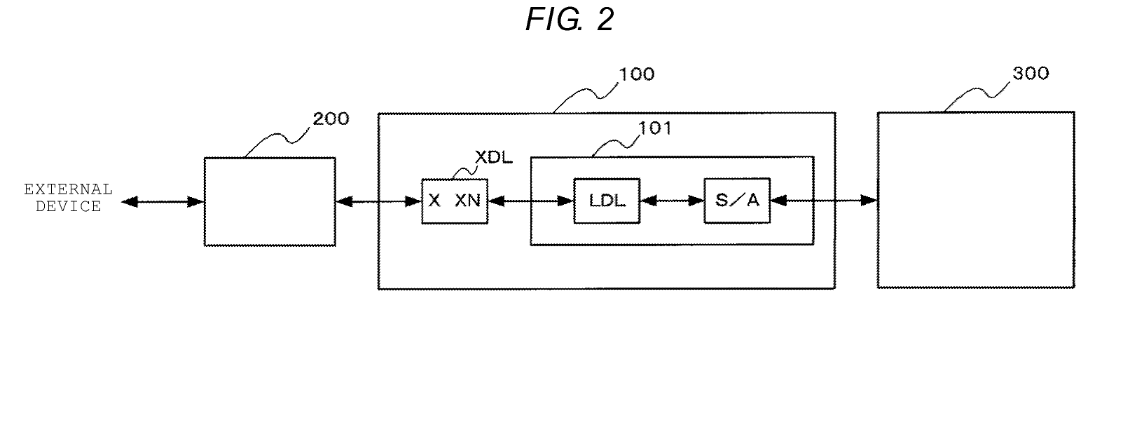

FIG. 2 illustrates an outline of input and output paths of the NAND flash memory including the bit line control circuit.

The bit line control circuit 100 performs inputting and outputting of data with an external device via data input and output buffer 200. Transmission of data is performed between the data input and output buffer 200 and the non-inverting data terminal X of the data latch XDL.

The bit line control circuit 100 includes a sense amplifier unit 101, and the data latch LDL is included in the sense amplifier unit 101. Data stored in the data latch LDL is written to a cell array 300 by a sense amplifier S/A, and data read from the cell array 300 is stored in the data latch LDL via the sense amplifier S/A.

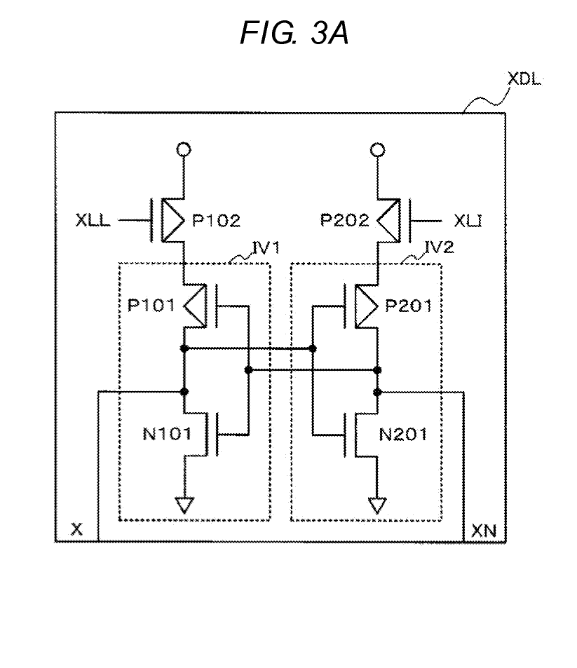

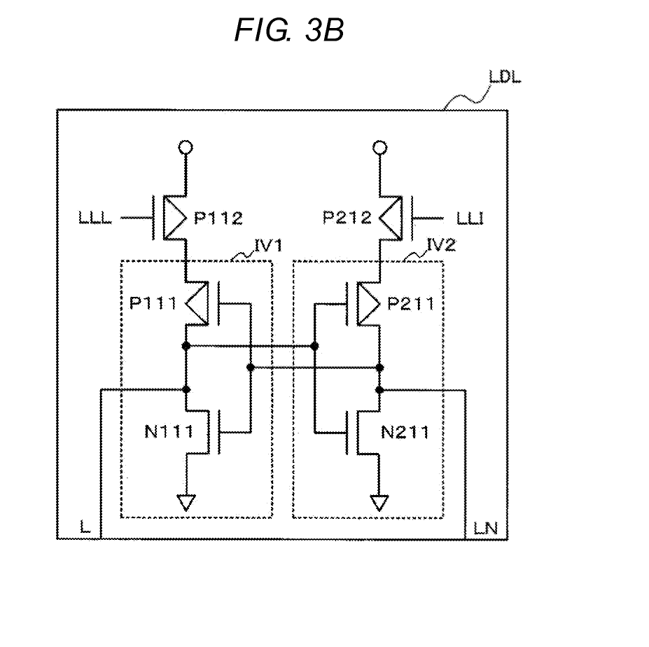

FIGS. 3A and 3B illustrate a circuit configuration example of the data latch XDL and the data latch LDL.

FIG. 3A illustrates a circuit configuration example of the data latch XDL.

The data latch XDL has an inverter IV1 including a PMOS transistor P101 and an NMOS transistor N101, an inverter IV2 including a PMOS transistor P201 and an NMOS transistor N201, a PMOS transistor P102 connected between the inverter IV1 and the power supply terminal, and a PMOS transistor P202 connected between the inverter IV2 and the power supply terminal.

An output terminal of the inverter IV1 is the non-inverting data terminal X, and an output terminal of the inverter IV2 is the inverting data terminal XN. The output terminal X of the inverter IV1 is connected to an input terminal of the inverter IV2, and the output terminal XN of the inverter IV2 is connected to an input terminal of the inverter IV1.

In addition, a control signal XLL is input to a gate terminal of the PMOS transistor P102, and a control signal XLI is input to a gate terminal of the PMOS transistor P202.

Data may be written to the data latch XDL by using either of the non-inverting data terminal X and the inverting data terminal XN. In this case, for example, if data is written from the non-inverting data terminal X, a value of the non-inverting data terminal X is set to ‘1’ in advance. Next, the control signal XLL is made to be turned to ‘1’ so as to turn off the PMOS transistor P102, thereby disconnecting the inverter IV1 from the power supply terminal.

Accordingly, if data to be written is ‘1’, an output of the inverter IV2 becomes ‘0’, and thus the NMOS transistor N101 remains turned off. Therefore, a value of the non-inverting data terminal X is maintained as ‘1’.

On the other hand, if data to be written is ‘0’, an output of the inverter IV2 becomes ‘1’, and thus the NMOS transistor N101 is turned on. Therefore, a value of the non-inverting data terminal X changes to ‘0’.

Similarly, if data is written from the inverting data terminal XN, a value of the inverting data terminal XN is set to ‘1’ in advance, and, then, the control signal XLI is turned to ‘1’.

FIG. 3B illustrates a circuit configuration example of the data latch LDL. The circuit configuration is the same as the configuration of the data latch XDL, and thus detailed description thereof will be omitted here.

In the data latch LDL, an output terminal of an inverter IV1 having a PMOS transistor P111 and an NMOS transistor N111 is the non-inverting data terminal L, and an output terminal of an inverter IV2 having a PMOS transistor P211 and an NMOS transistor N211 is the inverting data terminal LN.

In addition, a PMOS transistor P112 is connected between the inverter IV1 and the power supply terminal, and a PMOS transistor P212 is connected between the inverter IV2 and the power supply terminal. A control signal LLL is input to the PMOS transistor P112, and a control signal LLI is input to the PMOS transistor P212.

When data is written to the data latch LDL, the control signal LLL or the control signal LLI is set to ‘1’.

Referring to FIG. 1 again, the precharge control unit 1 includes an NMOS transistor N11 and an NMOS transistor N12 which are connected in series between the power supply terminal and the data bus DBUS. A gate terminal of the NMOS transistor N11 is connected to the inverting data terminal XN of the data latch XDL, and a control signal DPCX is input to a gate terminal of the NMOS transistor N12.

The control signal DPCX is a signal for controlling a timing of precharging the data bus DBUS when data is transmitted from the data latch XDL to the data latch LDL. The time when the control signal DPCX is ‘1’ is a precharge period of the data bus DBUS.

The precharge control unit 1 precharges the data bus DBUS, when the control signal DPCX is ‘1’, and a value of the inverting data terminal XN of the data latch XDL is ‘1’.

On the other hand, when a value of the inverting data terminal XN of the data latch XDL is ‘0’ even if the control signal DPCX is ‘1’, the precharge control unit 1 does not precharge the data bus DBUS.

If the transmission gate NT1 is turned on after the precharge period finishes, data of the inverting data terminal XN of the data latch XDL is transmitted to the data bus DBUS. At this time, since the data bus DBUS is not precharged when data of the inverting data terminal XN of the data latch XDL is ‘0’, movement of electric charge due to the transmission does not occur, and wasteful power consumption can be suppressed.

The precharge control unit 2 includes an NMOS transistor N21 and an NMOS transistor N22 which are connected in series between the power supply terminal and the data bus DBUS. A gate terminal of the NMOS transistor N21 is connected to the data bus LBUS, and a control signal DPCL is input to a gate terminal of the NMOS transistor N22.

The control signal DPCL is a signal for controlling a timing of precharging the data bus DBUS when data is transmitted from the data latch LDL to the data latch XDL. The time when the control signal DPCL is ‘1’ is a precharge period of the data bus DBUS.

The precharge control unit 2 precharges the data bus DBUS when the control signal DPCL is ‘1’, and a value on the data bus LBUS is ‘1’.

On the other hand, when a value on the data bus LBUS is ‘0’ even if the control signal DPCL is ‘1’, the precharge control unit 2 does not precharge the data bus DBUS.

If the transmission gate NT3 is turned on after the precharge period finishes, data is transmitted from the data bus LBUS to the data bus DBUS. At this time, since the data bus DBUS is not precharged when data on the data bus LBUS is ‘0’, movement of electric charge due to the transmission does not occur, and wasteful power consumption can be suppressed.

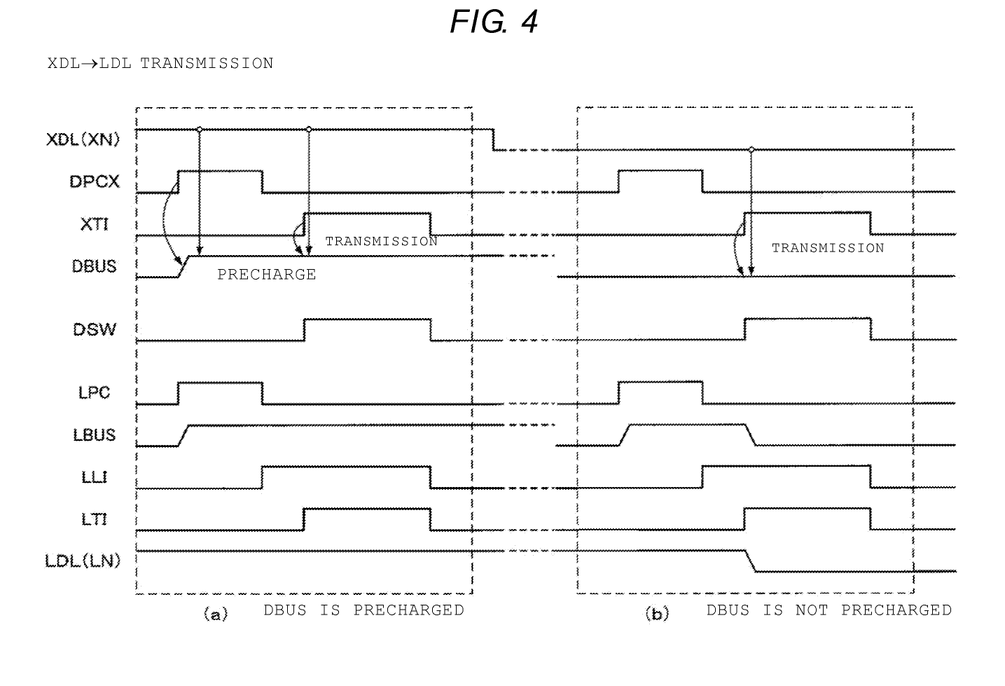

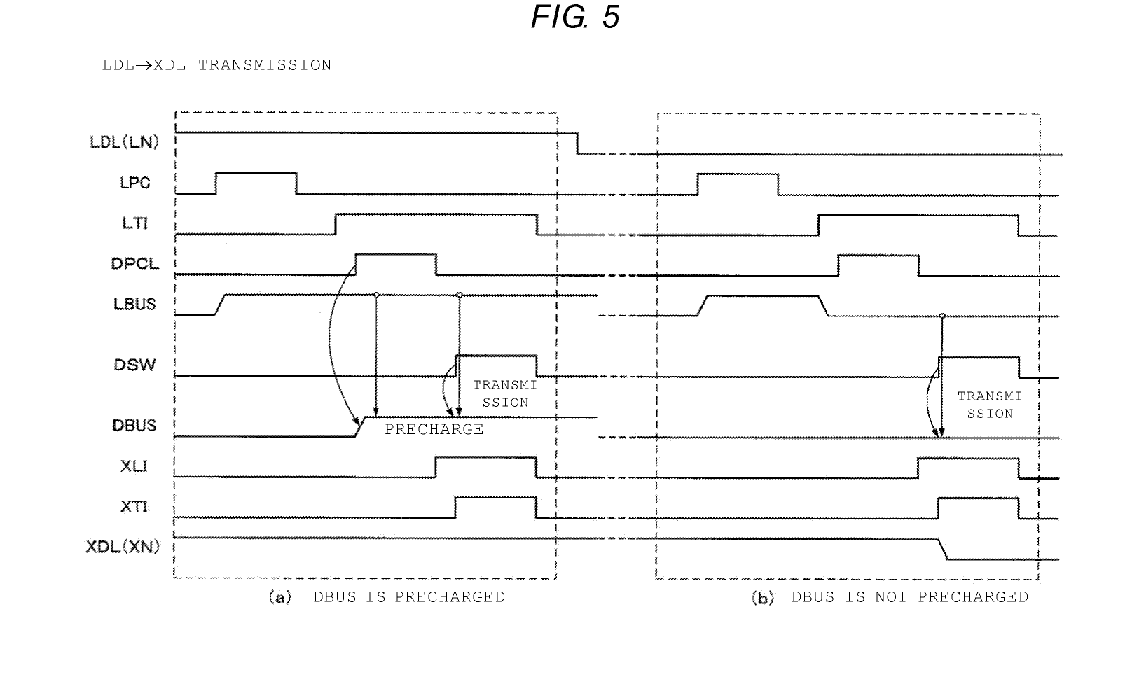

FIGS. 4 and 5 are waveform diagrams illustrating an example of a data transmission operation in the nonvolatile semiconductor memory device according to the present exemplary embodiment.

FIG. 4 illustrates an example of an operation of transmitting data from the data latch XDL to the data latch LDL.

First, as illustrated in (a) of FIG. 4, if data of the inverting data terminal XN of the data latch XDL is ‘1’, the precharge control unit 1 precharges the data bus DBUS to ‘1’ when the control signal DPCX is ‘1’. Next, if the control signal XTI becomes ‘1’, data of the inverting data terminal XN of the data latch XDL is transmitted to the data bus DBUS, and thus the data bus DBUS remains ‘1’ without change.

Successively, if a control signal DSW is turned to ‘1’, the data is transmitted from the data bus DBUS to the data bus LBUS. Here, since the data bus LBUS is precharged when the control signal LPC is ‘1’, a value of the data bus LBUS remains ‘1’ without change.

Here, assuming that data is written to the data latch LDL by using the inverting data terminal LN, the control signal LLI for turning off the PMOS transistor P212 of the data latch LDL is turned to ‘1’, and, then, the control signal LTI is turned to ‘1’. Accordingly, a value of the inverting data terminal LN of the data latch LDL is maintained as ‘1’ which is set in advance without change.

On the other hand, as illustrated in (b) of FIG. 4, if data of the inverting data terminal XN of the data latch XDL is ‘0’, the data bus DBUS is not precharged when the control signal DPCX is ‘1’. Next, if the control signal XTI becomes ‘1’, data of the inverting data terminal XN of the data latch XDL is transmitted to the data bus DBUS, and thus the data bus DBUS remains ‘0’ without change.

Successively, if the control signal DSW becomes ‘1’, the data is transmitted from the data bus DBUS to the data bus LBUS. Here, since the data bus LBUS is precharged when the control signal LPC is ‘1’, a value of the data bus LBUS changes from ‘1’ to ‘0’.

Next, the control signal LLI is turned to ‘1’, and, then, the control signal LTI is turned to ‘1’. Accordingly, a value of the inverting data terminal LN of the data latch LDL changes from ‘1’ which is set in advance to ‘0’.

FIG. 5 illustrates an example of an operation of transmitting data from the data latch LDL to the data latch XDL. Here, an example is illustrated in which data is output from the data latch LDL by using the inverting data terminal LN.

First, as illustrated in (a) of FIG. 5, if data of the inverting data terminal LN of the data latch LDL is ‘1’, when the control signal LTI becomes ‘1’, the data of the inverting data terminal LN of the data latch LDL is transmitted to the data bus LBUS, and a value of the data bus LBUS continuously remains 1 from the precharge by the control signal LPC.

Next, if the control signal DPCL is turned to ‘1’, the precharge control unit 2 precharges the data bus DBUS to ‘1’. Successively, if a control signal DSW is turned to ‘1’, the data on the data bus LBUS is transmitted to the data bus DBUS, and the data bus DBUS remains ‘1’ without change.

Next, the control signal XLI for turning off the PMOS transistor P202 of the data latch XDL is turned to ‘1’, and, then, the control signal XTI is turned to ‘1’. Accordingly, a value of the inverting data terminal XN of the data latch XDL is maintained as ‘1’ which is set in advance without change.

On the other hand, as illustrated in (b) of FIG. 5, if data of the inverting data terminal LN of the data latch LDL is ‘0’, a value of the data bus LBUS changes from the precharge state to ‘0’ when the control signal LTI is turned to ‘1’.

For this reason, even if the control signal DPCL is turned to ‘1’, the data bus DBUS is not precharged.

Then, if the control signal DSW is turned to ‘1’, the data on the data bus LBUS is transmitted to the data bus DBUS, and the data bus DBUS remains ‘0’ without change.

Next, the control signal XLI is turned to ‘1’, and, then, the control signal XTI is turned to ‘1’. Accordingly, a value of the inverting data terminal XN of the data latch XDL changes from ‘1’ which is set in advance to ‘0’.

As described above, in the nonvolatile semiconductor memory device according to the present exemplary embodiment, only when data stored in the data latch XDL or the data latch LDL which is a transmission source is ‘1’, the data bus DBUS is precharged.

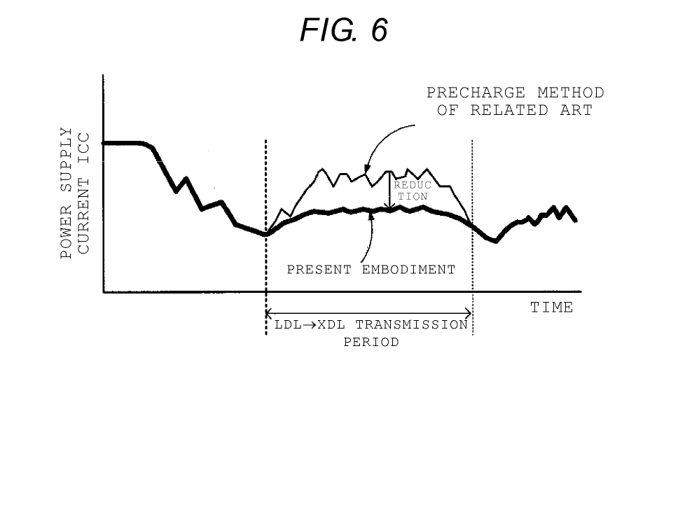

FIG. 6 illustrates a measurement example of a power supply current ICC during the transmission operation between the data latches of the nonvolatile semiconductor memory device according to the present embodiment. Here, an example is illustrated in which data is transmitted from the data latch LDL to the data latch XDL.

As illustrated in FIG. 6, the power supply current ICC in the data transmission period according to the present embodiment is reduced as compared with a method of the related art in which precharge is performed even when transmission data is ‘0’. This is because precharge is not performed when transmission data is ‘0’ in the present embodiment. In the present embodiment, the power supply current ICC in the data transmission period can be suppressed to approximately half on average as compared with the precharge method of the related art.

According to the present embodiment, since the data bus DBUS is not precharged when data stored in a data latch which is a transmission source is ‘0’, wasteful release of electric charge on the data bus DBUS can be suppressed, and thus power consumption of a data transmission operation between data latches can be reduced.

### Second Embodiment

In the above-described first embodiment, the precharge control unit 1 and the precharge control unit 2 are formed using two-stage NMOS transistors. For this reason, a precharge level of the data bus DBUS is a value obtained by subtracting threshold values of the two-stage NMOS transistors from a power supply voltage level.

Therefore, in the present embodiment, an example will be described in which a precharge level of the data bus DBUS can be used as a power supply voltage level.

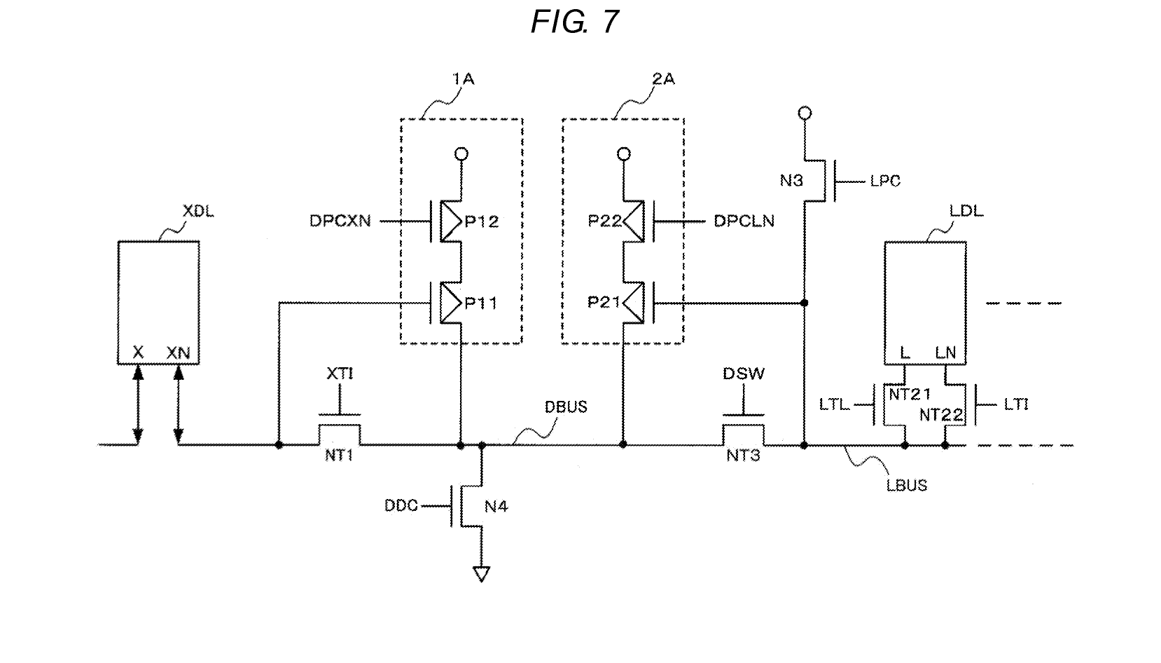

FIG. 7 is a circuit diagram illustrating an example of a configuration of a nonvolatile semiconductor memory device according to the second embodiment.

The present embodiment is different from the first embodiment in that the precharge control unit 1 is replaced with a precharge control unit 1A, and the precharge control unit 2 is replaced with a precharge control unit 2A.

The precharge control unit 1A includes a PMOS transistor P11 and a PMOS transistor P12 which are connected in series between the power supply terminal and the data bus DBUS. A gate terminal of the PMOS transistor P11 is connected to the inverting data terminal XN of the data latch XDL, and a control signal DPCXN is input to a gate terminal of the PMOS transistor P12.

The precharge control unit 2A includes a PMOS transistor P21 and a PMOS transistor P22 which are connected in series between the power supply terminal and the data bus DBUS. A gate terminal of the PMOS transistor P21 is connected to the data bus LBUS, and a control signal DPCLN is input to a gate terminal of the PMOS transistor P22.

As above, in the present embodiment, the precharge control unit 1A and the precharge control unit 2A are formed using the PMOS transistors. For this reason, a precharge level of the data bus DBUS can be used as the power supply voltage level.

However, a polarity of data transmitted to the data bus DBUS is inverted, and thus the transmission gate NT1 or NT3 cannot be turned on. For this reason, before an operation is performed, the data bus DBUS is required to be reset to aground potential by using the NMOS transistor N4. Therefore, a reduction rate of power is lower than in the first embodiment.

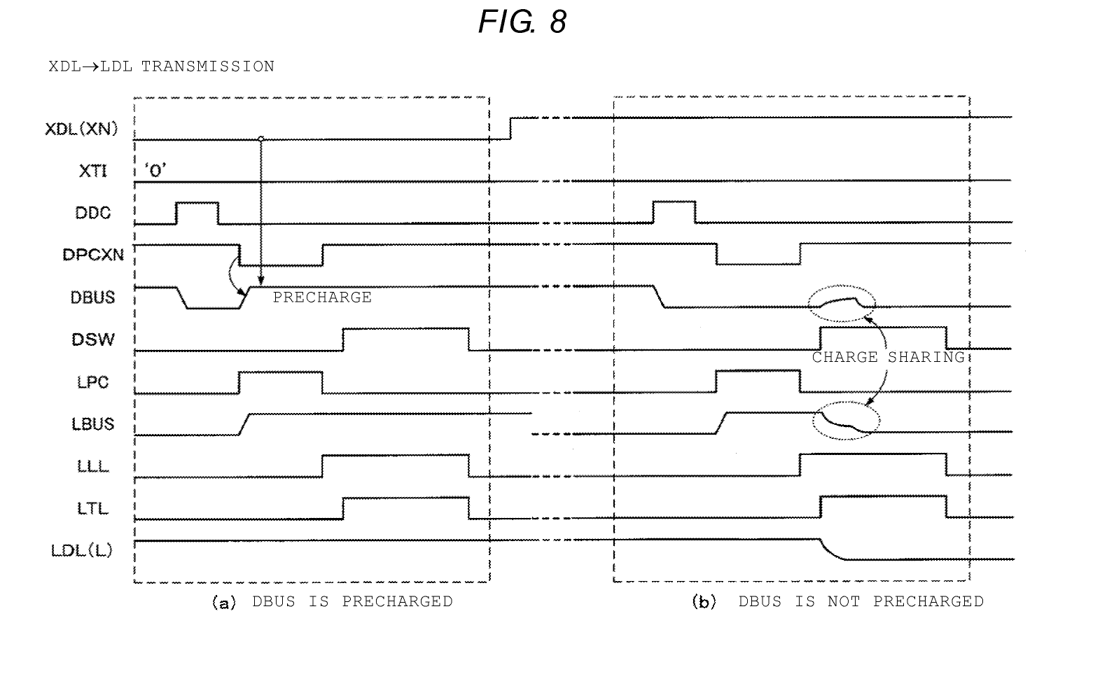

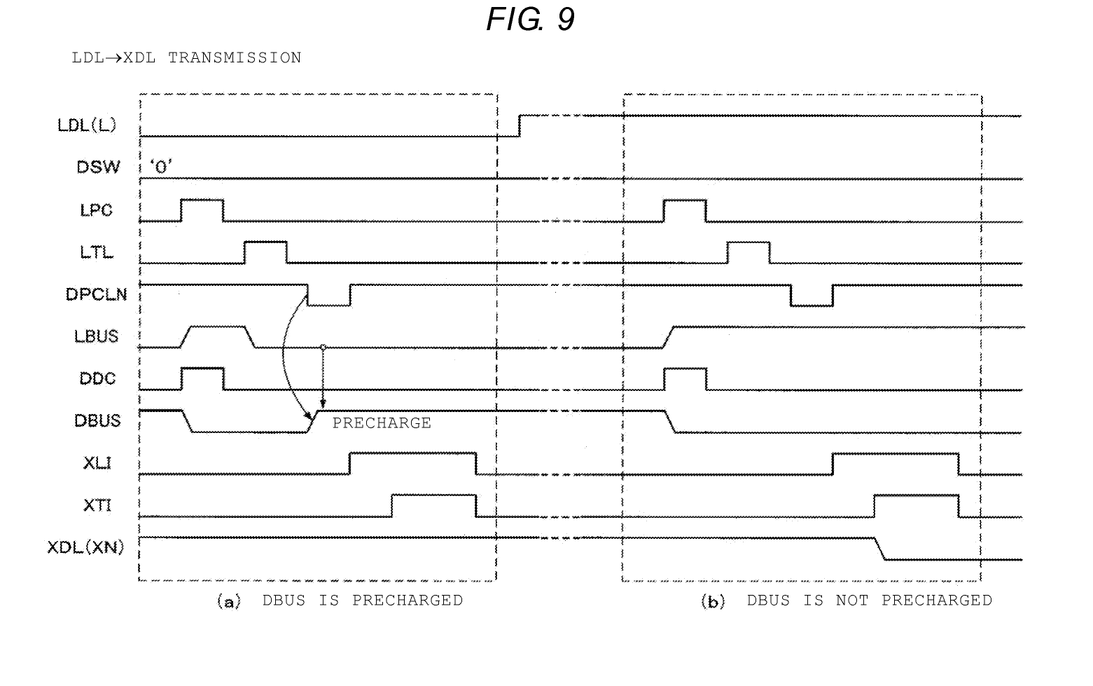

FIGS. 8 and 9 are waveform diagrams illustrating an example of a data transmission operation in the nonvolatile semiconductor memory device according to the present embodiment.

FIG. 8 illustrates an example of an operation of transmitting data from the data latch XDL to the data latch LDL. In this case, the control signal XTI is turned to ‘0’, and the transmission gate NT1 is turned off. In addition, before data is transmitted, a control signal DDC is turned to ‘1’, and the data bus DBUS is reset to the ground potential.

As illustrated in (a) of FIG. 8, if data of the inverting data terminal XN of the data latch XDL is ‘0’, when the control signal DPCXN is turned to ‘0’, the PMOS transistors P11 and P12 of the precharge control unit 1A are turned on together, and thus the data bus DBUS is precharged up to the power supply voltage level. At this time, a control signal LPC is also turned to ‘1’, and thus the data bus LBUS is also precharged.

Successively, the control signal DPCXN returns to ‘1’, but the level ‘1’ is maintained on the data bus DBUS even if the control signal DPCXN returns to ‘1’.

Next, if the control signal DSW is turned to ‘1’, the level ‘1’ on the data bus DBUS is transmitted to the data bus LBUS. Accordingly, a value on the data bus LBUS continuously remains ‘1’ from the precharge level.

As above, in the present embodiment, data with a polarity opposite to a polarity of data output from the inverting data terminal XN of the data latch XDL which is a transmission source is transmitted to the data bus LBUS. Therefore, in the present embodiment, data is made to be written to the data latch LDL by using the non-inverting data terminal L.

In this case, a control signal LLL for turning off the PMOS transistor P112 of the data latch LDL is turned to ‘1’, and, then, a control signal LTL is turned to ‘1’. Accordingly, a value of the non-inverting data terminal L of the data latch LDL is maintained as ‘1’ which is set in advance without change.

On the other hand, as illustrated in (b) of FIG. 8, if data of the inverting data terminal XN of the data latch XDL is ‘1’, the data bus DBUS is not precharged even if the control signal DPCXN is turned to ‘0’. For this reason, the data bus DBUS remains ‘0’. Thereafter, even if the control signal DPCXN returns to ‘1’, the data bus DBUS remains ‘0’.

In contrast, the data bus LBUS is precharged to be ‘1’ when the control signal LPC is turned to ‘1’. Thereafter, the level ‘1’ is maintained on the data bus LBUS even after the control signal LPC returns to ‘0’.

Next, if the control signal DSW is turned to ‘1’, the transmission gate NT3 is turned on, and thus the data bus DBUS is connected to the data bus LBUS. At this time, the data bus DBUS and the data bus LBUS are in a floating state together, and thus a charge sharing phenomenon occurs between a parasitic capacitor of the data bus DBUS and a parasitic capacitor of the data bus LBUS. Due to this charge sharing, electric charge accumulated in the parasitic capacitor of the data bus LBUS during the precharge is distributed to the parasitic capacitor of the data bus DBUS.

At this time, a capacitance value of the parasitic capacitor of the data bus DBUS is generally considerably larger than a capacitance value of the parasitic capacitor of the data bus LBUS, and thus, a potential of the data bus DBUS slightly increases. On the other hand, a potential of the data bus LBUS remarkably decreases.

For this reason, if data is written to the data latch LDL when the control signal LTL is ‘1’, a value of the non-inverting data terminal L of the data latch LDL changes to ‘0’ at a time point of exceeding a logical threshold value of the inverter IV2 of the data latch LDL.

FIG. 9 illustrates an example of transmitting data from the data latch LDL to the data latch XDL. Here, an example is illustrated in which data of the data latch LDL is output from the non-inverting data terminal L. In this case, the control signal DSW is ‘0’, and the transmission gate NT3 is turned off. In addition, before data is transmitted, the control signal DDC is ‘1’, and the data bus DBUS is reset to the ground potential.

As illustrated in (a) of FIG. 9, if data of the non-inverting data terminal L of the data latch LDL is ‘0’, first, the data bus LBUS is precharged when the control signal LPC is turned to ‘1’. Thereafter, if the control signal LTL is turned to ‘1’, the level ‘0’ is transmitted from the non-inverting data terminal L of the data latch LDL to the data bus LBUS.

Next, if the control signal DPCLN is turned to ‘0’, the PMOS transistors P21 and P22 of the precharge control unit 2A are turned on together, and thus the data bus DBUS is precharged up to the power supply voltage level.

Successively, the control signal DPCLN returns to ‘1’, but the level ‘1’ is maintained on the data bus DBUS even if the control signal DPCLN returns to ‘1’.

Therefore, in order to write data to the data latch XDL, the control signal XLI for turning off the PMOS transistor P202 of the data latch XDL is turned to ‘1’, and, then, the control signal XTI is turned to ‘1’. Accordingly, a value of the inverting data terminal XN of the data latch XDL is maintained as ‘1’ which is set in advance without change.

On the other hand, as illustrated in (b) of FIG. 9, if data of the non-inverting data terminal L of the data latch LDL is ‘1’, when the control signal LTL is turned to ‘1’, a value of the data bus LBUS continuously remains ‘1’ from the precharge state.

For this reason, even if the control signal DPCLN is turned to ‘0’, the data bus DBUS is not precharged but remains ‘0’.

Therefore, when the control signal XTI is turned to ‘1’, a value of the inverting data terminal XN of the data latch XDL changes from ‘1’ which is set in advance to ‘0’.

According to the present embodiment, the precharge control unit 1A and the precharge control unit 2A are formed using a PMOS transistor, and thus a precharge level of the data bus DBUS can be used as the power supply voltage level.

### Third Embodiment

Generally, the data bus DBUS is connected to a plurality of (for example, sixteen) data latches XDL. In this case, in the first embodiment or the second embodiment, the precharge control unit 1 or the precharge control unit 1A is required to be connected to each data latch XDL, and thus the number of transistors to be added for precharge increases.

Therefore, in the present embodiment, an example will be described in which, even if the number of data latches XDL connected to the data bus DBUS is large, the number of transistors to be added for precharge can be reduced.

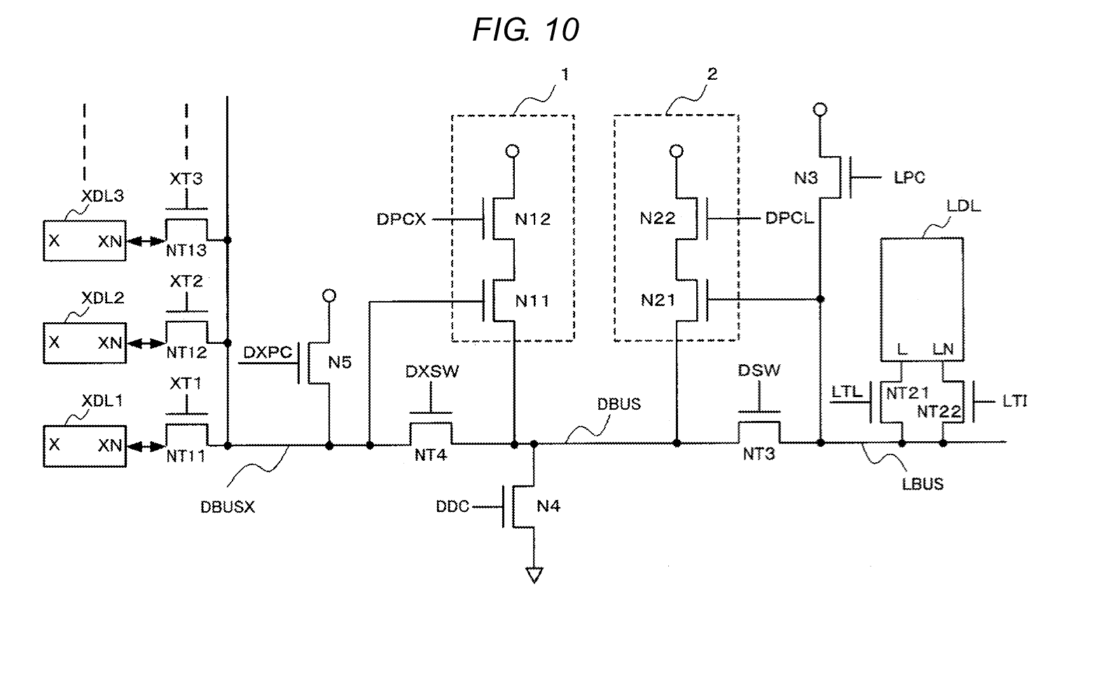

FIG. 10 is a circuit diagram illustrating an example of a configuration of a nonvolatile semiconductor memory device according to the third embodiment.

A fundamental configuration of a circuit illustrated in FIG. 10 is the same as in the first embodiment, but, here, transmission gates NT11, NT12, NT13, . . . are connected to respective inverting data terminals XN of a plurality of data latches XDL (XDL1, XDL2, XDL3, . . . ), and transmission of data to the respective data latches XDL is controlled using control signals XT1, XT2, XT3, . . . .

In the present embodiment, a transmission gate NT4 (a fourth transmission gate) is inserted in the middle of the data bus DBUS, one side thereof connected to the transmission gates NT11, NT12, NT13 (first transmission gates) being referred to as a data bus DBUSX (a third data bus), and the other side being referred to as a data bus DBUS (a fourth data bus). The transmission gate NT4 controls data transmission between the data bus DBUSX and the data bus DBUS by using a control signal DXSW.

In addition, in the present embodiment, the precharge control unit 1 precharges the data bus DBUS on the basis of a value of data which is transmitted from the data latches XDL1, XDL2, XDL3, . . . to the data bus DBUSX.

In addition, the data bus DBUSX is precharged by an NMOS transistor N5 which is controlled using a control signal DXPC.

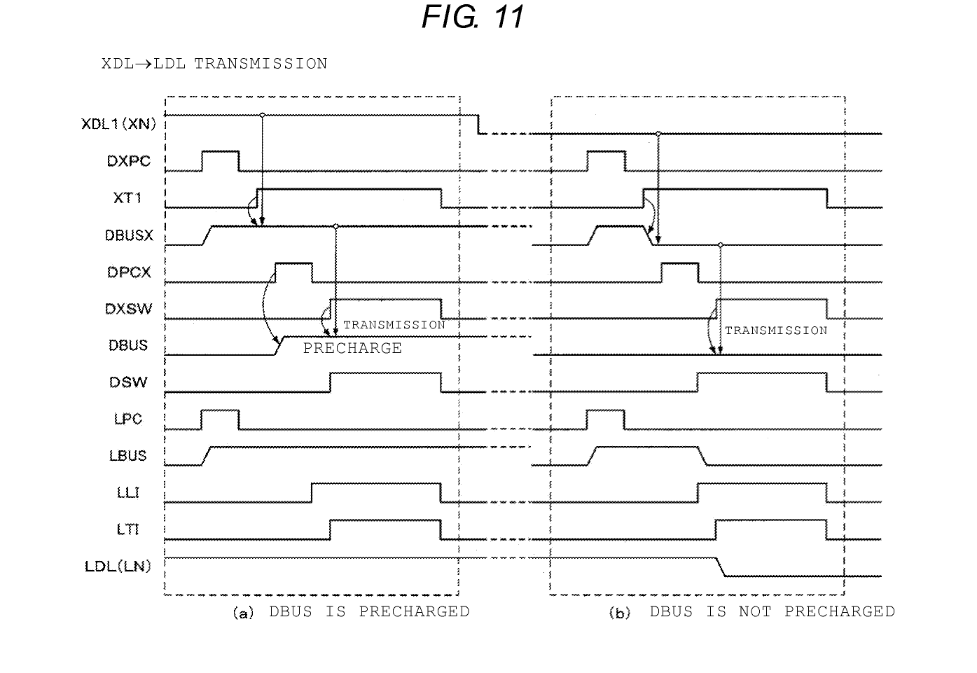

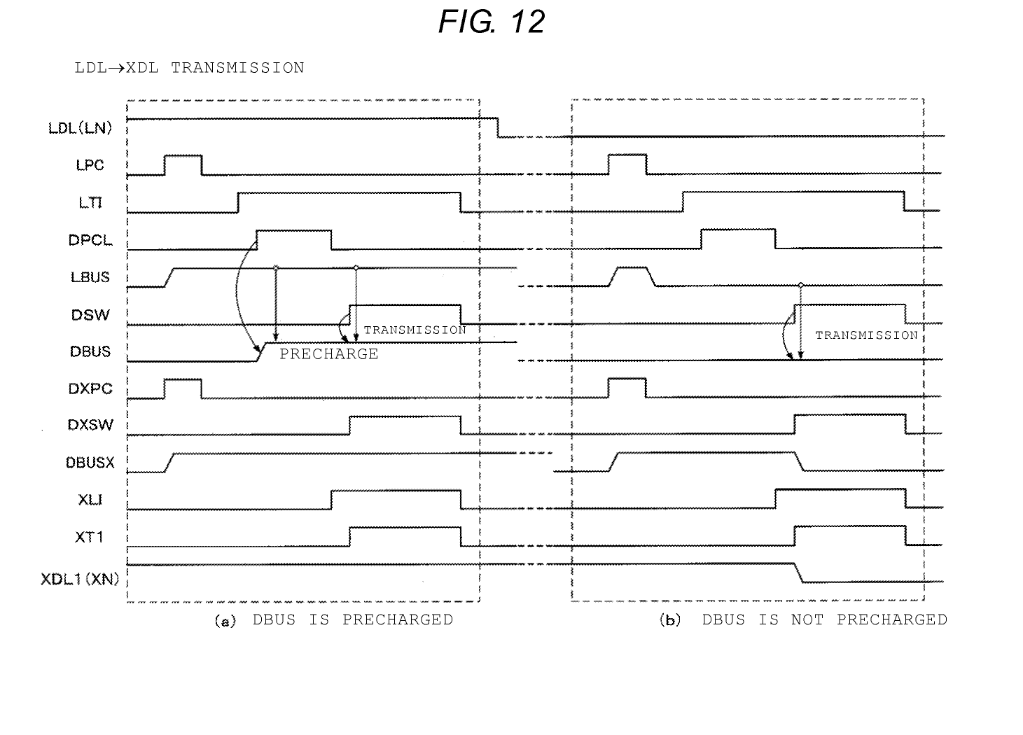

FIGS. 11 and 12 are waveform diagrams illustrating an example of a data transmission operation in the nonvolatile semiconductor memory device according to the present exemplary embodiment.

FIG. 11 illustrates an example of an operation of transmitting data from the data latch XDL1 to the data latch LDL.

First, as illustrated in (a) of FIG. 11, if data of the inverting data terminal XN of the data latch XDL1 is ‘1’, the control signal DXPC is turned to ‘1’ such that the data bus DBUSX is precharged, and, then, the control signal XT1 is turned to ‘1’. Therefore, data of the inverting data terminal XN of the data latch XDL1 is transmitted to the data bus DBUSX, and thus the data bus DBUSX is turned to ‘1’.

Next, the precharge control unit 1 precharges the data bus DBUS to ‘1’ when the control signal DPCX is turned to ‘1’.

Successively, if the control signal DXSW is turned to ‘1’, the data on the data bus DBUSX is transmitted to the data bus DBUS, and the data bus DBUS remains ‘1’ without change.

A subsequent operation is the same as in the first embodiment, and description thereof will be omitted here.

On the other hand, as illustrated in (b) of FIG. 11, if data of the inverting data terminal XN of the data latch XDL1 is ‘0’, data transmitted to the data bus DBUSX is ‘0’. Therefore, even if the control signal DPCX is turned to ‘1’, the data bus DBUS is not precharged.

Successively, if the control signal DXSW is turned to ‘1’, the data on the data bus DBUSX is transmitted to the data bus DBUS, and the data bus DBUS remains ‘0’ without change.

A subsequent operation is the same as in the first embodiment, and description thereof will be omitted here.

FIG. 12 illustrates an example of an operation of transmitting data from the data latch LDL to the data latch XDL1. Here, an example is illustrated in which data is output from the data latch LDL by using the inverting data terminal LN.

First, as illustrated in (a) of FIG. 12, if data of the inverting data terminal LN of the data latch LDL is ‘1’, in the same manner as in the first embodiment, the precharge control unit 2 precharges the data bus DBUS to ‘1’ when the control signal DPCL is turned to ‘1’. Successively, if a control signal DSW is turned to ‘1’, the data on the data bus LBUS is transmitted to the data bus DBUS, and the data bus DBUS remains ‘1’ without change.

Next, if a control signal DXSW is turned to ‘1’, the data on the data bus DBUSX is transmitted to the data bus DBUS. Here, the data bus DBUSX is precharged when the control signal DXPC is ‘1’, and thus remains ‘1’ without change.

Next, the control signal XL1 for turning off the PMOS transistor P202 of the data latch XDL1 is turned to ‘1’, and, then, the control signal XT1 is turned to ‘1’. Accordingly, a value of the inverting data terminal XN of the data latch XDL1 is maintained as ‘1’ which is set in advance without change.

On the other hand, as illustrated in (b) of FIG. 12, if data of the inverting data terminal LN of the data latch LDL is ‘0’, in the same manner as in the first embodiment, even if the control signal DPCL is turned to ‘1’, the data bus DBUS is not precharged.

According to the present embodiment, data of a plurality of data latches XDL is temporarily transmitted to the data bus DBUSX, and the precharge control unit 1 controls precharge of the data bus DBUS according to a value of the data transmitted to the data bus DBUSX. For this reason, even if the number of data latches XDL is large, a single precharge control unit 1 can control precharge of the data bus DBUS, and thus the number of transistors to be added for precharge can be reduced.

In addition, although the data bus DBUSX is required to be precharged, the data bus DBUSX is shorter than the data bus DBUS in wire length, and thus a wire capacitance thereof is also less. For this reason, power consumption due to the precharge is much smaller than in a case of precharging the data bus DBUS at all times, and thus overall power consumption can be reduced.

### Fourth Embodiment

Although, in the above-described respective embodiments, a precharge level is fixed to ‘1’ when data is transmitted from the data latch XDL to the data bus DBUS, in the present embodiment, an example will be described in which a precharge level changes between ‘1’ and ‘0’ depending on transmission data.

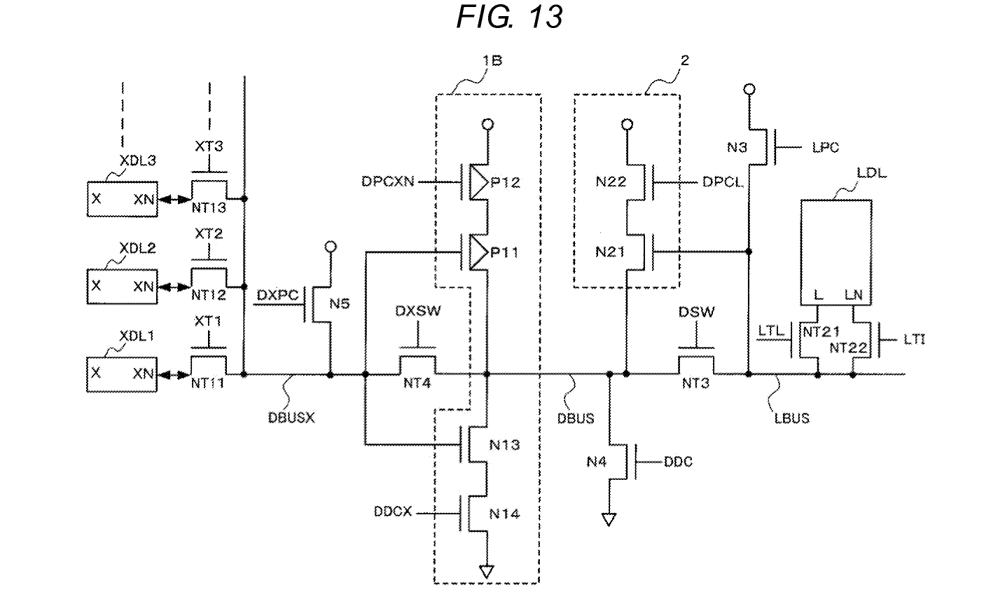

FIG. 13 is a circuit diagram illustrating an example of a configuration of a nonvolatile semiconductor memory device according to the fourth embodiment.

In the example illustrated in FIG. 13, the precharge control unit 1 of the third embodiment is replaced with a precharge control unit 1B.

The precharge control unit 1B includes a PMOS transistor P11 and a PMOS transistor P12 which are connected in series between the data bus DBUS and the power supply terminal, and an NMOS transistor N13 and an NMOS transistor N14 which are connected in series between the data bus DBUS and the ground terminal.

A gate terminal of the PMOS transistor P11 is connected to the data bus DBUSX, and a control signal DPCXN is input to a gate terminal of the PMOS transistor P12.

In addition, a gate terminal of the NMOS transistor N13 is connected to the data bus DBUSX, and a control signal DDCX is input to a gate terminal of the NMOS transistor N14.

The control signal DPCXN and the control signal DDCX are signals for controlling a timing of precharging the data bus DBUS when data is transmitted from the data bus DBUSX to the data bus DBUS. When the control signal DPCXN is ‘0’ and the control signal DPCX is ‘1’, the precharge control unit 1B precharges the data bus DBUS.

At this time, the precharge control unit 1B precharges the data bus DBUS to ‘1’ when data transmitted to the data bus DBUSX is ‘0’, and precharges the data bus DBUS to ‘0’ when data transmitted to the data bus DBUSX is ‘1’.

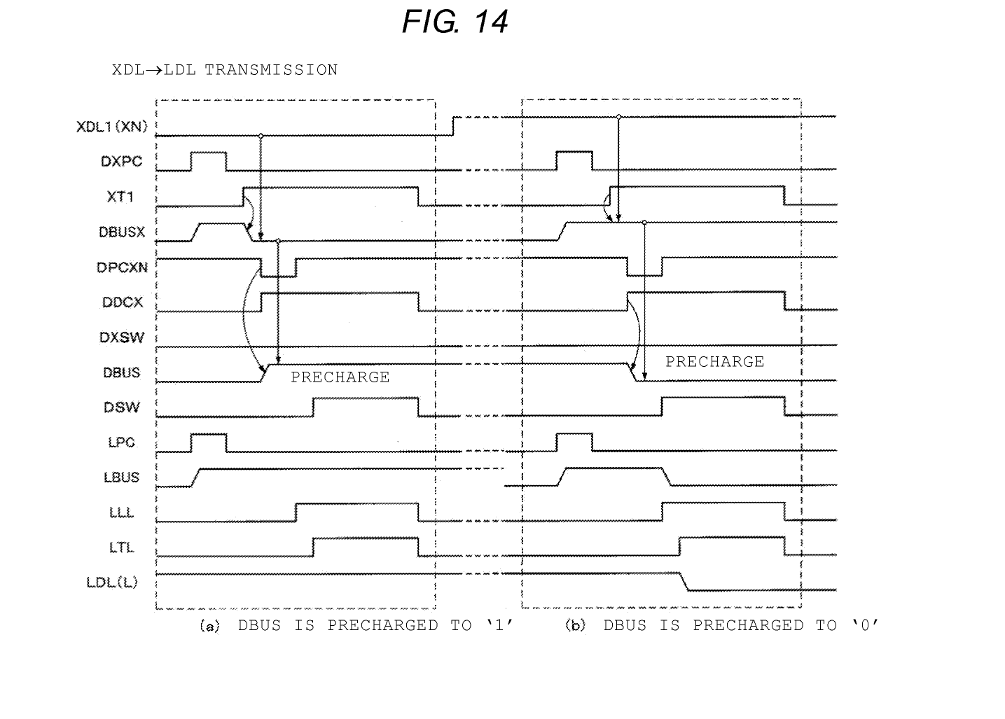

FIG. 14 illustrates an example of an operation of transmitting data from the data latch XDL1 to the data latch LDL.

As illustrated in (a) of FIG. 14, if data of the inverting data terminal XN of the data latch XDL1 is ‘0’, the level ‘0’ is transmitted to the data bus DBUSX. Therefore, when the control signal DPCXN is turned to ‘1’, the PMOS transistor P11 and the PMOS transistor P12 of the precharge control unit 1B are turned on together such that the data bus DBUS is precharged to ‘1’.

On the other hand, as illustrated in (b) of FIG. 14, if data of the inverting data terminal XN of the data latch XDL1 is ‘1’, the level ‘1’ is transmitted to the data bus DBUSX. Therefore, when the control signal DDCX is turned to ‘1’, the NMOS transistor N13 and the NMOS transistor N14 of the precharge control unit 1B are turned on together such that the data bus DBUS is precharged to ‘0’.

In addition, in the present embodiment, if the transmission gate NT4 is made to remain turned off, the precharge control unit 1B may be used as an inverter which inverts data on the data bus DBUSX for transmission to the data bus DBUS.

Accordingly, as illustrated in FIG. 14, data with a polarity opposite to a polarity of data output from the inverting data terminal XN of the data latch XDL1 can be stored in the data latch LDL.

According to the present embodiment, the data bus DBUS can be precharged to ‘1’ or ‘0’ according to a value of data transmitted to the data bus DBUSX. In addition, if the transmission gate NT4 is made to remain turned off, data on the data bus DBUSX can be inverted so as to be transmitted to the data bus DBUS.

### Fifth Embodiment

In the present embodiment, a description will be made of an example of a nonvolatile semiconductor memory device which can perform logical calculation between data stored in the data latch XDL and data stored in the data latch LDL along with mutual data transmission between the data latch XDL and the data latch LDL.

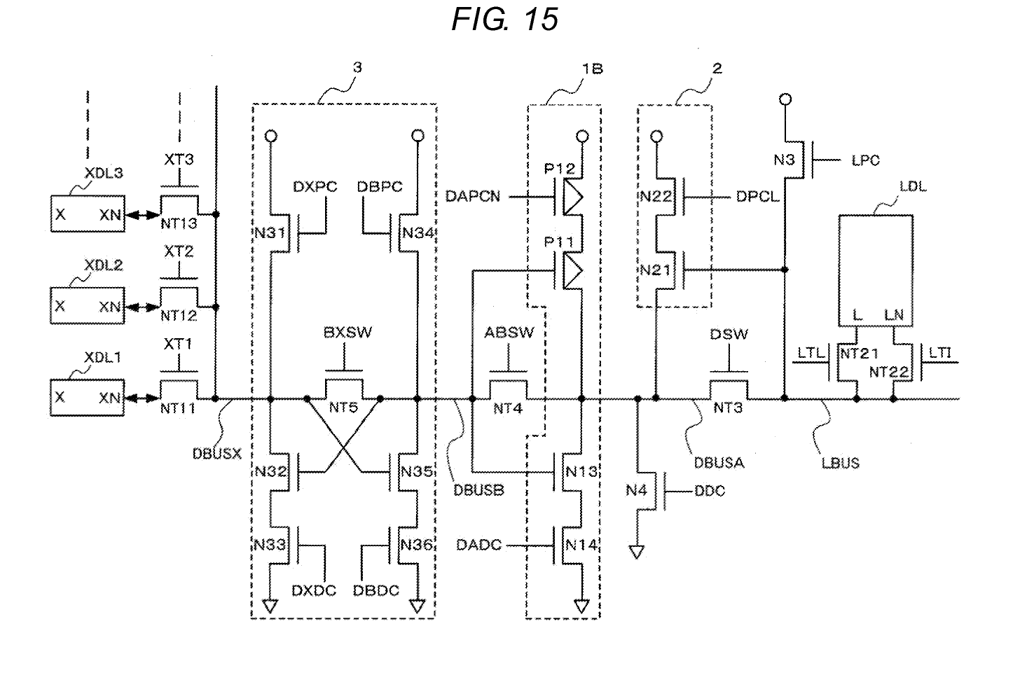

FIG. 15 is a circuit diagram illustrating an example of a configuration of a nonvolatile semiconductor memory device according to the fifth embodiment.

In the example illustrated in FIG. 15, a calculation unit 3 which performs changing between non-inverting and inverting of a polarity of data on the data bus DBUSX is inserted in the middle of the data bus DBUSX of the circuit of the third embodiment.

The calculation unit 3 has a transmission gate NT5 which transmits data with a non-inverted polarity on the data bus DBUSX. The transmission gate NT5 is formed by an NMOS transistor, and a control signal BXSW is input to a gate terminal thereof.

With the insertion of the transmission gate NT5 and the transmission gate NT4, a data bus between the transmission gate NT1 and the transmission gate NT5 is referred to as a data bus DBUSX, a data bus between the transmission gate NT5 and the transmission gate NT4 is referred to as a data bus DBUSB, and a data bus between the transmission gate NT4 and the transmission gate NT3 is referred to as a data bus DBUSA.

In addition, the calculation unit 3 has an NMOS transistor N31 connected between the data bus DBUSX and the power supply terminal, an NMOS transistor N32 and an NMOS transistor N33 which are connected in series between the data bus DBUSX and the ground terminal, an NMOS transistor N34 connected between the data bus DBUSX and the power supply terminal, and an NMOS transistor N35 and an NMOS transistor N36 which are connected in series between the data bus DBUSB and the ground terminal.

A control signal DXPC is input to a gate terminal of the NMOS transistor N31, a gate terminal of the NMOS transistor N32 is connected to the data bus DBUSB, and a control signal DXDC is input to a gate terminal of the NMOS transistor N33.

Similarly, a control signal DBPC is input to a gate terminal of the NMOS transistor N34, a gate terminal of the NMOS transistor N35 is connected to the data bus DBUSX, and a control signal DBDC is input to a gate terminal of the NMOS transistor N36.

When the control signal DXPC is ‘1’, the data bus DBUSX is precharged, and when control signal DBPC is ‘1’, the data bus DBUSB is precharged.

In contrast, when the control signal DXDC is ‘1’, inverted data of data on the data bus DBUSB is transmitted to the data bus DBUSX, and when control signal DBDC is ‘1’, inverted data of data on the data bus DBUSX is transmitted to the data bus DBUSB.

A logical calculation in the present embodiment is performed by writing data to a transmission destination data latch. At this time, if a transmission destination data latch and a transmission source data latch are directly connected to each other via a bus line, when data of the transmission destination data latch is ‘0’, and data of the transmission source data latch is ‘1’, the data of the transmission source data latch is replaced with ‘0’ and is thus destroyed.

Therefore, in the present embodiment, during writing of data when a logical calculation is performed, at least one of the transmission gate NT4 and the transmission gate NT5 is turned off so that the transmission destination data latch is not directly connected to the transmission source data latch when data is written to the transmission destination data latch.

Accordingly, when the logical calculation is performed, data of the transmission source data latch can be prevented from being destroyed.

As above, in the present embodiment, since data can be transmitted even if data of the transmission destination data latch is ‘0’, a logical calculation between data of the transmission source data latch and data of the transmission destination data latch can be performed along with the transmission of the data.

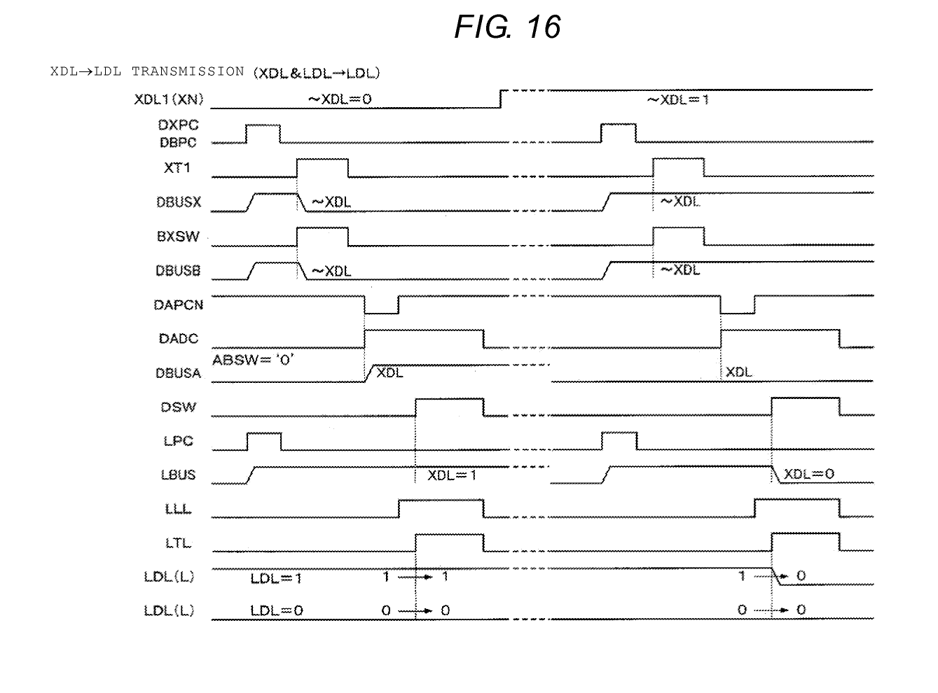

An example of this logical calculation operation will be described with reference to FIGS. 16 to 20. In addition, here, non-inverted data of the data latch XDL is indicated by XDL, inverted data thereof is indicated by ˜XDL, non-inverted data of data latch LDL is indicated by LDL, and inverted data thereof is indicated by ˜LDL.

FIG. 16 illustrates an example in which a result of an AND calculation (XDL&LDL) of XDL and LDL is written to the non-inverting data terminal L of the data latch LDL when data is transmitted from the data latch XDL1 to the data latch LDL. In this case, a control signal ABSW is ‘0’ at all times so as to turn off the transmission gate NT4.

˜XDL which is output from the inverting data terminal XN of the data latch XDL1 is transmitted to the data bus DBUSX when the control signal XT1 is ‘1’, and is transmitted to the data bus DBUSB when the control signal BXSW is ‘1’.

Next, the data is inverted by the precharge control unit 1B, and thus XDL is transmitted to the data bus DBUSA, when a control signal DAPCN is ‘0’, and the control signal DADC is ‘1’.

Therefore, when the control signal DSW is ‘1’, XDL is transmitted to the data bus LBUS. XDL on the data bus LBUS is written to the non-inverting data terminal L of the data latch LDL when the control signal LTL is ‘1’.

At this time, if LDL before being written is LDL=1, LDL after being written is LDL=1 at XDL=1, and LDL=0 at XDL=0. On the other hand, if LDL before being written is LDL=0, LDL after being written is LDL=0 at both of XDL=1 and XDL=0.

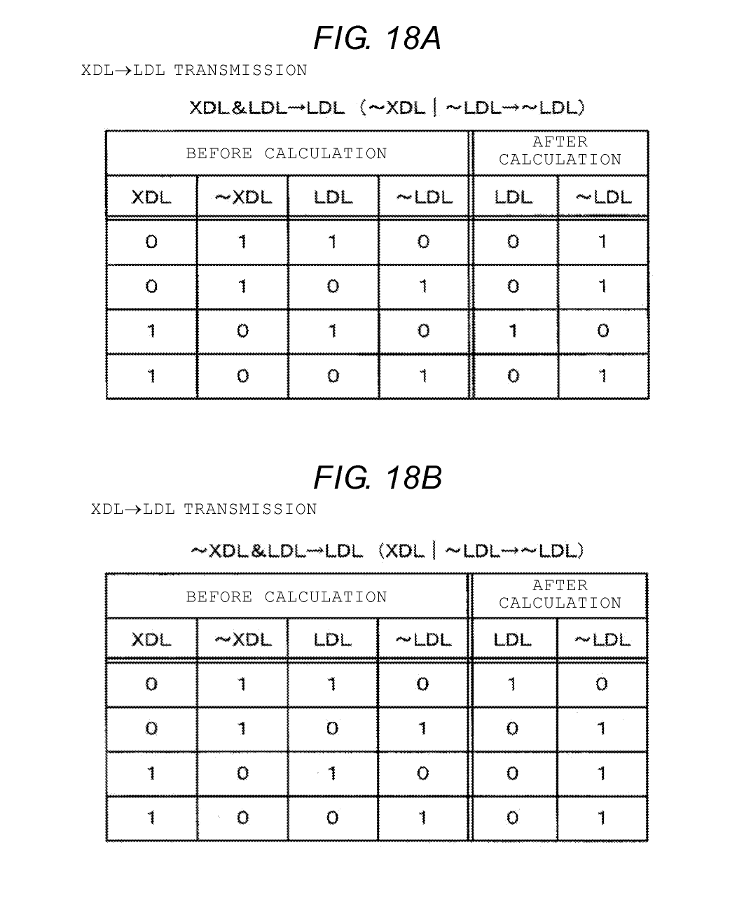

FIG. 18A illustrates a relationship between values of XDL and LDL in the transmission operation by using a truth table. As illustrated in the truth table, it can be seen that a result of an AND calculation (XDL&LDL) of XDL and LDL is stored in the data latch LDL as LDL due to the transmission operation illustrated in FIG. 16.

In addition, this transmission operation may be regarded as an operation in which a result of an OR calculation (˜XDL|˜LDL) of ˜XDL and ˜LDL is stored in the data latch LDL as ˜LDL.

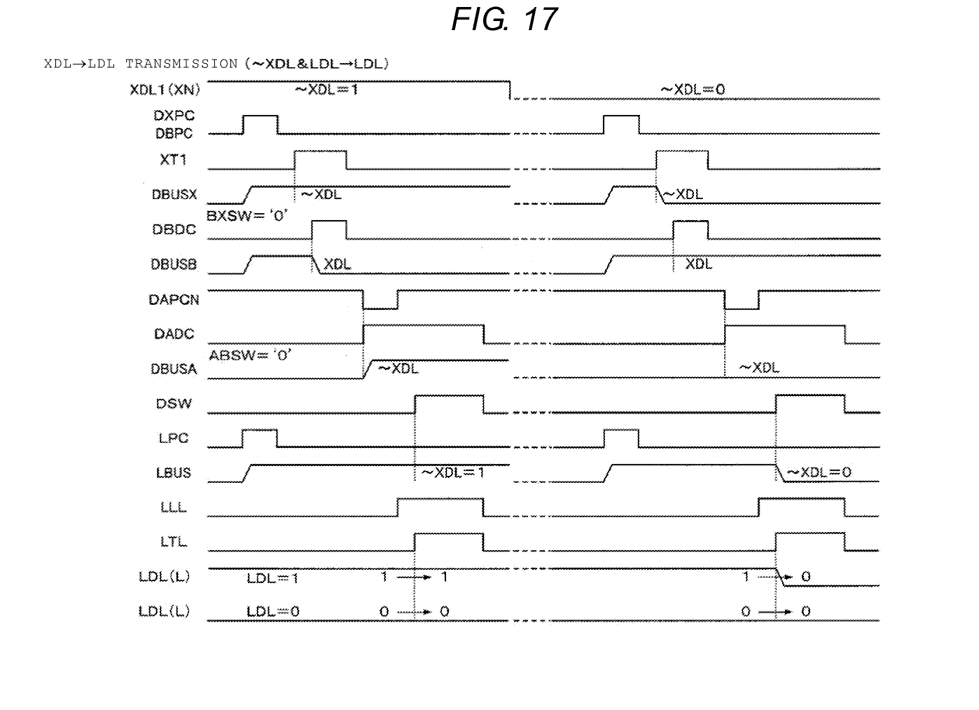

FIG. 17 illustrates an example in which a result of an AND calculation (˜XDL&LDL) of ˜XDL and LDL is written to the non-inverting data terminal L when data is transmitted from the data latch XDL1 to the data latch LDL. In this case, the control signal ABSW and the control signal BXSW are ‘0’ at all times so as to turn off the transmission gates NT4 and NT5.

An operation of this example is different from the operation illustrated in FIG. 16 in that data on the data bus DBUSX is inverted by the calculation unit 3 and is then transmitted to the data bus DBUSB. In other words, when the control signal DBDC is ‘1’, XDL is transmitted to the data bus DBUSB.

XDL is inverted by the precharge control unit 1B again, and thus ˜XDL is transmitted to the data bus LBUS.

FIG. 18B illustrates a relationship between values of ˜XDL and LDL in the transmission operation by using a truth table. As illustrated in the truth table, it can be seen that a result of an AND calculation (˜XDL&LDL) of ˜XDL and LDL is stored in the data latch LDL as LDL due to the transmission operation illustrated in FIG. 17.

In addition, this transmission operation may be regarded as an operation in which a result of an OR calculation (XDL|˜LDL) of XDL and ˜LDL is stored in the data latch LDL as ˜LDL.

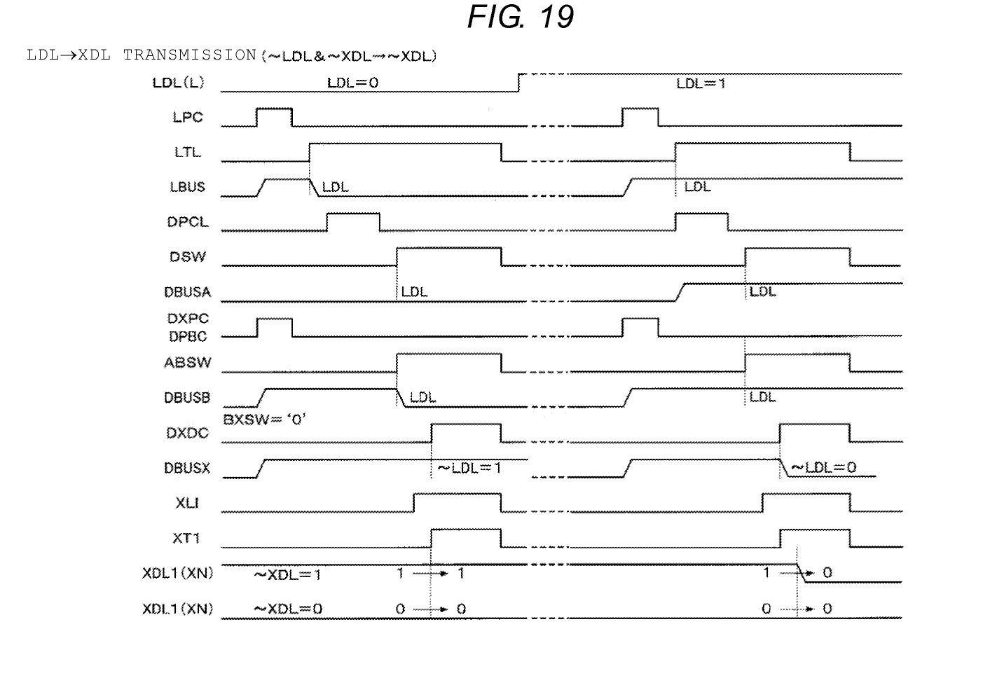

FIG. 19 illustrates an example in which a result of an AND calculation (˜LDL&˜XDL) of ˜LDL and ˜XDL is written to the inverting data terminal XN of the data latch XDL1 when data is transmitted from the data latch LDL to the data latch XDL1. In this case, the control signal ABSW is ‘0’ at all times so as to turn off the transmission gate NT4.

LDL which is output from the non-inverting data terminal L of the data latch LDL is transmitted to the data bus LBUS when the control signal LTL is ‘1’, LDL is transmitted to the data bus DBUSA when the control signal DSW is ‘1’, and LDL is transmitted to the data bus DBUSB when the control signal ABSW is ‘1’.

LDL transmitted to the data bus DBUSB is inverted by the calculation unit 3 when the control signal DXDC is ‘1’, and is then transmitted to the data bus DBUSX as ˜LDL.

˜LDL on the data bus DBUSX is written to the inverting data terminal XN of the data latch XDL1 when the control signal XT1 is ‘1’.

At this time, if ˜XDL before being written is ˜XDL=1, ˜XDL after being written is ˜XDL=1 at ˜LDL=1, and ˜XDL=0 at ˜LDL=0. On the other hand, if ˜XDL before being written is ˜XDL=0, ˜XDL after being written is ˜XDL=0 at both of ˜LDL=1 and ˜LDL=0.

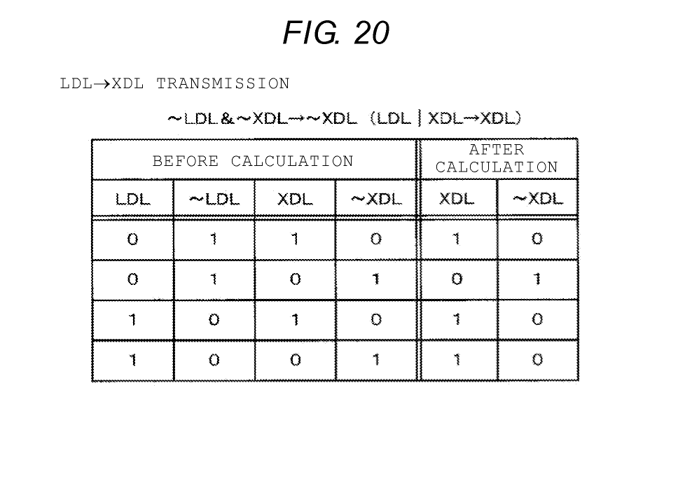

FIG. 20 illustrates a relationship between values of ˜LDL and ˜XDL in the transmission operation by using a truth table. As illustrated in the truth table, it can be seen that a result of an AND calculation (˜LDL&˜XDL) of ˜LDL and ˜XDL is stored in the data latch XDL as ˜XDL due to the transmission operation illustrated in FIG. 19.

In addition, this transmission operation may be regarded as an operation in which a result of an OR calculation (LDL|XDL) of LDL and XDL is stored in the data latch XDL as ˜XDL.

According to the present embodiment, a logical calculation can be performed between data stored in the data latch XDL and data stored in the data latch LDL along with mutual data transmission between the data latch XDL and the data latch LDL. Accordingly, since a calculation process is not required to be performed again after data is transmitted, power consumption related to a data calculation can be reduced, and time required in the data calculation can be reduced.

According to the nonvolatile semiconductor memory device and the data transmission method of at least one of the above-described embodiments, power consumption can be reduced and a data calculation can be performed speedily.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a first data latch;
a second data latch;
a data bus;
a first transistor electrically connected between the first data latch and the data bus;
a second transistor electrically connected between the second data latch and the data bus;
a control unit configured to control charging of the data bus based on an output of the first data latch.

2. The device according to claim 1, wherein the control unit is configured to electrically connect the data bus to a power supply when the output of the first data latch is at a first level and to electrically disconnect the data bus from the power supply when the output of the first data latch is at a second level.

3. The device according to claim 2, wherein the control unit includes a transistor electrically connected between the power supply and the data bus, a gate of the transistor being electrically connected to the output of the first data latch.

4. The device according to claim 3, wherein the transistor turns on when the output of the first data latch is at a high level and turns off when the output of the first data latch is at a low level.

5. The device according to claim 3, wherein the transistor turns on when the output of the first data latch is at a low level and turns on when the output of the first data latch is at a low level.

6. The device according to claim 1, further comprising:
a discharge transistor electrically connected between the data bus and ground.

7. The device according to claim 1, further comprising:
a third data latch electrically connected to the first transistor in parallel with the first data latch; and
third and fourth transistors that are controlled to selectively connect one of the first and third data latches to the data bus.

8. A nonvolatile semiconductor memory device comprising:
a first data latch;
a second data latch;
a data bus;
a first transistor electrically connected between the first data latch and the data bus;
a second transistor electrically connected between the data bus and the second data latch;
a first control unit configured to control charging of the data bus based on an output of the first data latch when data is being transferred from the first data latch to the second data latch; and
a second control unit configured to control charging of the data bus based on an output of the second data latch when data is being transferred from the second data latch to the first data latch.

9. The device according to claim 8, wherein the first control unit includes a third transistor including a gate that is electrically connected to the output of the first data latch, and the second control unit includes a fourth transistor including a gate that is electrically connected to the output of the second data latch.

10. The device according to claim 8, further comprising:
a discharge transistor electrically connected between the data bus and ground.

11. The device according to claim 8, further comprising:
a third data latch electrically connected to the first transistor in parallel with the first data latch; and
third and fourth transistors that are controlled to selectively connect one of the first and third data latches to a bus segment that is between the third and fourth transistors and the first transistor.

12. The device according to claim 11, wherein the first control unit includes a third transistor including a gate that is electrically connected to the bus segment.

13. The device according to claim 12, wherein the third transistor turns on when the bus segment is at a high level and turns off when the bus segment is at a low level.

14. The device according to claim 12, wherein the third transistor turns off when the bus segment is at a high level and turns on when the bus segment is at a low level.

15. The device according to claim 11, further comprising:
a calculation unit electrically connected to a portion of the bus segment and configured to perform changing of a polarity of data on the bus segment,
wherein the calculation unit is configured to control the polarity of the data to perform a logical calculation between data stored in the first data latch and data stored in the second data latch.

16. A method of transferring data between first and second data latches of a nonvolatile semiconductor memory device, said method comprising:
during a pre-charging period, connecting a data bus between the first and second data latches to a pre-charging power supply when a data of a first logic level is being transferred; and
during the pre-charging period, disconnecting the data bus from the pre-charging power supply when a data of a second logic level is being transferred.

17. The method of claim 16, wherein the data bus is connected to and disconnected from the pre-charging power supply using a transistor that is connected between the pre-charging power supply and the data bus.

18. The method of claim 17, wherein the transistor is an NMOS transistor, and the first logic level is a high level and the second logic level is a low level.

19. The method of claim 17, wherein the transistor is a PMOS transistor, and the first logic level is a low level and the second logic level is a high level.

20. The method of claim 17, further comprising:
after the pre-charging period, connecting the output of the first latch to the data bus.
